(19) United States
(12) Patent Application Publication
(10) Pub. No.: US 2015/0295015 A1
(43) Pub. Date: Oct. 15, 2015

(54) DOUBLE-SIDED DISPLAY AND METHOD OF MANUFACTURING SAME

(71) Applicant: SHENZHEN ROYOLE TECHNOLOGIES CO., LTD., Shenzhen (CN)

(72) Inventors: Xiaojun YU, Shenzhen (CN); Peng WEI, Shenzhen (CN); Zihong LIU, Shenzhen (CN)

(21) Appl. No.: 14/688,468

(22) Filed: Apr. 16, 2015

Related U.S. Application Data
(63) Continuation-in-part of application No. PCT/CN2012/083032, filed on Oct. 16, 2012.

(51) Int. Cl. H01L 27/32; H01L 27/12

(52) U.S. Cl. CPC H01L 27/3267; H01L 27/1218; H01L 27/124; H01L 27/1259; H01L 27/3276; H01L 2227/323

(57) ABSTRACT

A double-sided display and a method of manufacturing the double-side display are provided. The double-sided display includes a substrate having a plurality of holes penetrating through the substrate, a TFT driving circuit, a front-side light-emitting structure, a back-side light-emitting structure, and a plurality of driving electrodes. The front-side and the back-side light-emitting structures are respectively disposed on two opposite sides of the substrate. The TFT driving circuit is disposed on one of the two opposite sides, and the driving electrodes are disposed on the other one of the two opposite sides. The TFT driving circuit is configured to drive one of the front-side and back-side light-emitting structures to display images, and is further configured to drive the other one of the front-side and back-side light-emitting structures to display images in cooperation with the driving electrodes connected to the TFT driving circuit via the holes.

### CROSS REFERENCES OF RELATED APPLICATION

This application is a Continuation-In-Part of International Patent Application No. PCT/CN2012/083032, file on Oct. 16, 2012, which is hereby incorporated by reference in its entirety.

### TECHNICAL FIELD

The disclosure relates to the field of display technologies, and more particularly to a double-sided display and a method of manufacturing the double-sided display.

### BACKGROUND

With the advancement of technologies and evolvement of product specifications, double-sided displays are gradually used to display the same or different information, such that viewers standing at different positions may see the information conveniently.

However, a double-sided display employs two independent displays assembled back to back, thus resulting in a thicker and heavier product.

What is needed, therefore, is a double-sided display and a method of manufacturing the same which can overcome the described limitations.

### SUMMARY

The present disclosure provides a double-sided display and a method of manufacture the double-sided display.

One embodiment of the present disclosure discloses a double-sided display. The double-sided display includes a driving circuit substrate having a first surface, a second surface opposite to the first surface, and a plurality of holes penetrating through the driving circuit substrate from one of the first and second surfaces to the other one of the first and second surfaces, a front-side light-emitting structure disposed on one of the first and second surfaces, a back-side light-emitting structure disposed on the other of the first and second surfaces, a plurality of conductive connections located in the holes, a plurality of driving electrodes disposed between one of the first and second surfaces and one of the front-side and back-side light-emitting structures, and a TFT driving circuit disposed between the other one of the first and second surfaces and the other one of the front-side and back-side light-emitting structures, and the TFT driving circuit connected to the driving electrodes via the conducting connections. The TFT driving circuit drives one of the front-side and back-side light-emitting structures to display images, and drives the other one of the front-side and back-side light-emitting structures to display images in cooperation with the driving electrodes.

Another embodiment of the present disclosure discloses a double-sided display. The double-sided display includes a driving circuit substrate having a first surface and a second surface opposite to the first surface, a front-side light-emitting structure disposed on one of the first and second surfaces, a back-side light-emitting structure disposed on the other one of the first and second surfaces, and a TFT driving circuit disposed on one of the first and second surfaces, and configured to drive the front-side and back-side light-emitting structures to display images.

Another embodiment of the present disclosure discloses a method of manufacturing a double-sided display. The method includes: providing a driving circuit substrate comprising a first surface, a second surface opposite to the first surface, and a plurality of holes penetrating through the driving circuit substrate from one of the first and second surfaces to the other one of the first and second surfaces; providing a TFT driving circuit on one of the first and second surfaces of the driving circuit substrate; providing driving electrodes on the other one of the first and second surfaces of the driving circuit substrate, and the driving electrodes connected to the TFT driving circuit via the holes; and providing a front-side light-emitting structure on one of the first and second surfaces, and providing a back-side light-emitting structure on the other one of the first and second surfaces. The TFT driving circuit is located between one of the first and second surfaces and one of the front-side and back-side light-emitting structures, and the driving electrodes are located between the other one of the first and second surfaces and the other one of the front-side and back-side light-emitting structures.

Using the techniques described herein, the TFT driving circuit configured to drive the front-side light-emitting structure and the back-side light-emitting structure is disposed on an identical side of the driving circuit substrate, and fabricated via one single TFT manufacturing processing, therefore, the double-sided display becomes thinner, lighter and cheaper compared with a conventional double-sided display.

### BRIEF DESCRIPTION OF DRAWINGS

FIG. 1 is a cross-sectional view of a double-sided display according to a first embodiment of the disclosure;

FIG. 2 is a cross-sectional view of a double-sided display according to a second embodiment of the disclosure; and

FIG. 3 is a flowchart showing a method for manufacturing a double-sided display according to an embodiment of the disclosure.

### DETAILED DESCRIPTION

To make the objects, features and advantages of the disclosure described above more obvious and easy to be understood, in the following, particular embodiments of the disclosure are illustrated in detail in conjunction with drawings. It should be understood that, the described embodiments are only used to explain the disclosure, but not to limit the disclosure.

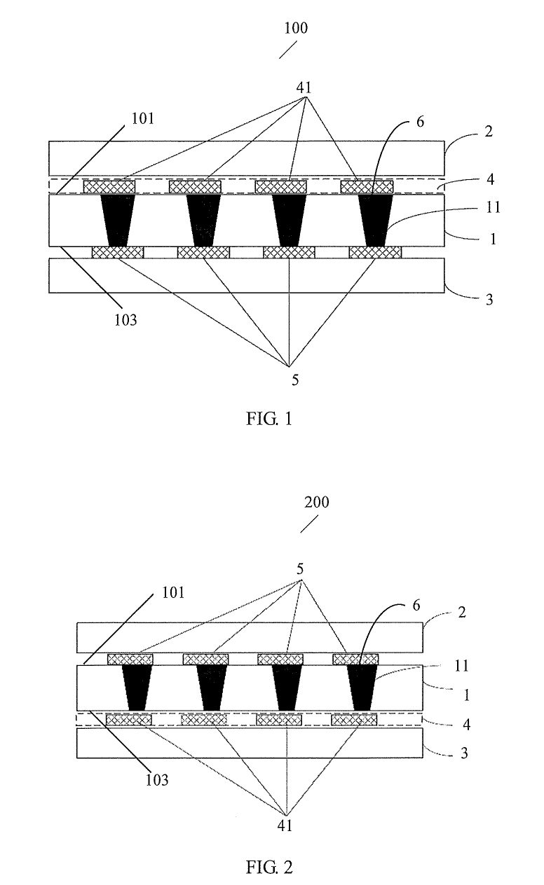

FIG. 1 shows a cross-sectional view of a double-sided display according to a first embodiment of the disclosure. For ease of description, only a part relevant to this embodiment is shown.

The double-sided display 100 includes a driving circuit substrate 1, a front-side light-emitting structure 2, a back-side light-emitting structure 3, a thin film transistor (TFT) driving circuit 4, a plurality of driving electrodes 5, and a plurality of conductive connections 6.

The driving circuit substrate 1 includes a first surface 101, a second surface 103 opposite to the first surface 101, and a plurality of holes 11 penetrating through the diving circuit substrate 3 from one of the first and second surfaces 101, 103 to the other of the first and second surfaces 101, 103.

The TFT driving circuit 4 includes a plurality of TFT units 41 configured to connect to and drive the front-side light-emitting structure 2 and the back-side light-emitting structure 3.

The front-side light-emitting structure 2 and the back-side light-emitting structure 3 are disposed on two opposite sides of the driving circuit substrate 1. The front-side light-emitting structure 2 faces the first surface 101. The back-side light-emitting structure 3 faces the second surface 103.

The TFT driving circuit 4 is disposed between the first surface 101 and the front-side light-emitting structure 2. The driving electrodes 6 are disposed between the second surface 103 and the back-side light-emitting structure 3. The holes 11 are filled with the conductive connections 6. The driving electrodes 5 correspond to the holes 11 in a one-to-one manner, and are connected to the TFT units 41 via the conductive connections 6. The TFT driving circuit 4 is configured to drive the front-side light emitting structure 2 to display images. The TFT driving circuit 4 is further configured to drive the back-side light emitting structure 3 to display images in cooperation with the driving electrodes 5.

In this embodiment, the front-side light-emitting structure 2 and back-side light-emitting structure 3 share one TFT driving circuit 4. When the double-sided display 100 operates, the TFT driving circuit 4 is configured to simultaneously drive the front-side light-emitting structure 2 and the back-side light-emitting structure 3. Correspondingly, the front-side light-emitting structure 2 and the back-side light-emitting structure 3 may simultaneously display identical images, for example. Accordingly, the double-sided display 100 achieves dual display.

In alternative embodiments, the double-sided display 100 includes two TFT driving circuits 4. The front-side light-emitting structure 2 and back-side light-emitting structure 3 are respectively driven by the two TFT driving circuits 4 instead of sharing one TFT driving circuit 4. That is, one of the two TFT driving circuits 4 is configured to drive the front-side light-emitting structure 2 to display images, and the other of the two TFT driving circuits 4 is configured to driving the back-side light-emitting structure 3 to display images. The two TFT driving circuits 4 are both disposed on the first surface 101 of the driving circuit substrate 1. The two TFT driving circuits 4 respectively output identical video signals or different video signals to the front-side light-emitting structure 2 and the back-side light-emitting structure 3, and identical or different images may be correspondingly displayed on both sides of the double-side display 100. Accordingly, the double-sided display 100 achieves double-sided independent display, and functions of the double-sided display 100 are further enriched.

The driving circuit substrate 1 may be a non-transparent substrate, for example. Accordingly, the front-side light-emitting structure 2 and the back-side light-emitting structure 3 do not interfere with each other when the double-sided display 100 displays images.

Further, types of the front-side light-emitting structure 2 and the back-side light-emitting structure 3 are not limited. Both of the front-side light-emitting structure 2 and the back-side light-emitting structure 3 may be active light-emitting structures, or passive light-emitting structures, for example. Or one of the front-side light-emitting structure 2 and the back-side light-emitting structure 3 may be an active light-emitting structure, and the other may be a passive light-emitting structure, for example. The active light emitting structures may be LEDs, or OLEDs, for example. The passive light-emitting structures may be, LCDs, or E-inks.

If the front-side and back-side light-emitting structures 2, 3 are OLEDs, the driving electrodes 5 may be anodes connected to the TFT units 41, for example. If the front-side and back-side light-emitting structures 2, 3 are LCDs, the driving electrodes 5 may be pixel electrodes connected to the TFT units 41, for example. Each of the driving electrodes 5 may be one of two electrodes of a pixel. The other one of the two electrodes are included in the light-emitting structure. Each side of the double-sided displays 100 includes a plurality of pixels for displaying images. Further, the driving electrodes of the front-side light-emitting structure 2 are disposed on one side of the driving circuit substrate 1 with the front-side light-emitting structure 2, and the driving electrodes of the back-side light-emitting structure 3 are disposed on the other side of the driving circuit substrate 1 with the back-side light-emitting structure 3.

Further, in the embodiment, the back-side light-emitting structure 3 and the front-side light-emitting structure 2 share one driving circuit substrate 1. In alternative embodiments, the double-sided display 100 includes two driving circuit substrates 1. The back-side light-emitting structure 3 and the front-side light-emitting structure 3 are respectively disposed on the two driving circuit substrates 1. The two driving circuit substrates 1 are disposed back to back. The holes 11 pass through the two driving circuit substrates 1. The TFT driving circuit 4 configured to drive the front-side light-emitting structure 2 and the back-side light-emitting structure 3 is disposed on the same side of one of the two driving circuit substrates 1, and the driving electrodes 5 are disposed on the other one of the two driving circuit substrates 1.

FIG. 2 shows a cross-sectional view of a double-sided display according to a second embodiment of the disclosure, wherein elements shown in FIG. 2 identical with elements shown in FIG. 1 are designated with the same reference numerals. The double-sided display 200 is similar to the double-sided display 100, and the differences between the double-sided display 200 and the double-sided display 100 lie in that positions of the driving circuit 4 and the driving electrodes 5 are exchanged, the front-side light-emitting structure 2 is driven by the TFT driving circuit 4 in cooperation with the driving electrodes 5 connected to the TFT units 41 through conductive connections 6 located in the holes 11 of the driving circuit substrate 1, and the back-side light-emitting structure 3 is driven by the TFT driving circuit 4. Working principles and driving effects of the foregoing two double-sided displays 100, 200 are similar or identical and are not strictly limited in the embodiments.

In the disclosure, since the TFT driving circuit 4 configured to drive the front-side light-emitting structure 2 and the back-side light-emitting structure 3 is disposed on an identical side of the driving circuit substrate 1, the driving electrodes 5 are disposed on a side that is not provided with the TFT driving circuit 4 of the driving circuit substrate 1, the double-sided displays 100, 200 becomes thinner, lighter and, cheaper compared with a conventional double-sided display.

Furthermore, the double-sided displays 100, 200 may be driven, in an active drive manner, and therefore, the double-sided displays 100, 200 can be large-size displays. Moreover, types of the front-side light-emitting structure 2 and the back-side light-emitting structure 3 on the two opposite sides are not necessarily limited to the same type, may be randomly combined, and are not restrictive. The front-side light-emitting structure 2 and the back-side light-emitting structure 3 are further capable of displaying images independently.

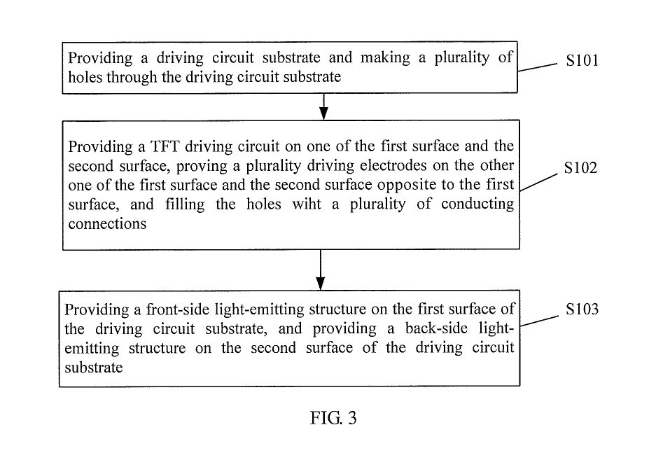

Referring to FIG. 3, a method for manufacturing a double-sided display is described as follows. The double-sided display may be the double-sided displays 100, 200 described above, for example. Accordingly, the fabrication method is described with the double-sided displays 100, 200 shown in FIGS. 1-2. Furthermore, the method is not limited to the description described below. The several steps in the manufacturing method may be reversed, some of the steps may be omitted and other steps may be added, which will be apparent to those skilled in the art that various changes in the details of the disclosure may be made within the spirit hereof.

Step S101: providing a driving circuit substrate 1 and making a plurality of holes 11 penetrate through the driving circuit substrate 1.

The driving circuit substrate 1 may be a non-transparent substrate, so as to avoid interference when the two sides display images. The non-transparent may be a glass substrate, or a film substrate, for example. The driving circuit substrate 1 includes a first surface 101 and a second surface 103 opposite to the first surface 101.

Step S102: providing a TFT driving circuit 4 on one of the first surface 101 and the second surface 103, proving a plurality driving electrodes 5 on the other one of the first surface 101 and the second surface 103, and filling the holes 11 with a plurality of conducting connections 6.

The TFT driving circuit 4 includes a plurality of TFT units 41. The driving electrodes 5 correspond to the holes 11 in a one-to-one manner and are connected to the TFT units 41 via the conductive connections 6 located in the holes 11.

Step S103: providing a front-side light-emitting structure 2 on the first surface 101 of the driving circuit substrate 1, and providing a back-side light-emitting structure 3 on the second surface 103 of the driving circuit substrate 1.

In step S101 of this embodiment, the number and locations of the holes 11 may be set according to the number and locations of preset driving electrodes 5, and the number and locations of the driving electrodes 5 are corresponding in a one-to-one manner to the number and locations of pixels in a pre-configured light-emitting structure on the same side of the driving circuit substrate 1 with the driving electrodes 5.

Further, in step S102, one set of the TFT driving circuit 4 may be provided, and the number of TFT units 41 in this TFT driving circuit 4 is the same as the number of pixels in the front-side and back-side light-emitting structures 2, 3. In this case, the double-sided displays 100, 200 share the one set of the TFT driving circuit 4 and the double-sided displays 100, 200 can be implemented by inputting signals from the one set of the TFT driving circuit 4, and images displayed on the two opposite sides may be identical, for example.

In alternative embodiments, in step S102, two sets of the TFT driving circuits 4 may be provided, and the number of the TFT units 41 in each of the two sets of the TFT driving circuits 4 is the same as the number of pixels in a respectively corresponding light-emitting structure. One of the two sets of the TFT driving circuits 4 is connected to the driving electrodes 5 via the holes 11 and is configured to drive a light-emitting structure on the same side of the driving circuit substrate 1 with the driving electrodes 5, and the other one of the two sets of the TFT driving circuits 4 is configured to drive a light-emitting structure on the same side of the driving circuit substrate 1 with the other one of the two sets of the TFT driving circuits 4. In this way, the two sets of the TFT driving circuits 4 may respectively drive the front-side and back-side light-emitting structures 2, 3, so that light-emitting statuses of the front-side and back-side light-emitting structures 2, 3 are mutually independent without interfering with each other.

In addition, the TFT driving circuit 4 and the driving electrodes 5 are separately disposed on different sides of the driving circuit substrate 1, and locations of the TFT driving circuit 4 and the driving electrodes 5 are not strictly limited.

In this embodiment, both of the front-side light-emitting structure 2 and the back-side light-emitting structure 3 may be active or passive light-emitting structures, for example. Or one of the front-side light-emitting structure 2 and the back-side light-emitting structure 3 is an active light-emitting structure, and the other one is a passive light-emitting structure. For example, a combination manner such as OLED/OLED, OLED/E-ink, and OLED/LCD is used. This embodiment may use but is not limited to the foregoing several combination manners.

It may be understood that after the front-side and back-side light-emitting structures 2, 3 are produced or assembled as described above, a process of connecting and packaging the TFT driving circuit 4 may further be performed. The TFT driving circuit 4 is connected to another control circuit of the double-sided display, so as to transmit electrical signals to the TFT driving circuit, and control a light-emitting status of a pixel in a light-emitting structure to display images. Certainly, the process of connecting and packaging the TFT driving circuit 4 may also not be performed temporarily, and the TFT driving circuit 4 may be connected and packaged during subsequent product assembly.

Further, in step S102, the sequence of a substep of providing the TFT driving circuit 4 on one of the first surface 101 and the second surface 103, a substep of providing the driving electrodes 5 on the other one of the first surface 101 and the second surface 103, and a substep of filling the holes 11 with a plurality of conducting connections 6 are not strictly limited, and may be reversed.

Further, if the TFT driving circuit 4 is firstly disposed on the driving circuit substrate 1, a protective film may be directly disposed on a surface of the TFT driving circuit 4. Then, the driving electrodes 5 and a corresponding light-emitting structure are disposed on the other side of the driving circuit substrate 1. The protective film above the TFT driving circuit 4 is then removed, and a light-emitting structure is disposed above the TFT driving circuit 4. Similarly, if the driving electrodes 5 are firstly disposed, a protective film is directly disposed on a surface of the driving electrodes 5. Then, the TFT driving circuit 4 and a light-emitting structure are disposed on the other side of the driving circuit substrate 1. The protective film above the driving electrodes 5 is then removed, and a light-emitting structure is disposed above the driving electrodes 5. In this way, in a manufacturing process, the TFT driving circuit 4 or the driving electrodes 5 can be protected from the interference of external environments.

In the method provided in the disclosure, the foregoing double-sided displays 100, 200 may be produced. In this method, a TFT driving circuit 4 and driving electrodes 5, and front-side and back-side light-emitting structures 2, 3 are respectively disposed on two opposite sides of a driving circuit substrate 1, so that the TFT driving circuit 4 disposed on the same side of the driving circuit substrate 1 can drive pixels in the light-emitting structures on the two opposite sides of the driving circuit substrate 1 to emit light, and the front-side and back-side light-emitting structures 2, 3 can display identical or different images, thereby implementing double-sided display or even double-sided independent display. In addition, types of the light-emitting structures on the two opposite sides are not limited to the same type in this method, and therefore, the double-sided display can be more widely applied. Furthermore, in this method, the TFT driving circuit 4 needs to be disposed on the same side of the driving circuit substrate 1, and the driving electrodes 5 is disposed on the other side, and the driving electrodes 5 are disposed on the other side that is not provided with the TFT driving circuit 4 of the driving circuit substrate 1, accordingly, manufacturing processes are greatly simplified, thereby reducing costs. Moreover, the double-sided displays 100, 200 drive, in an active drive manner, pixels to emit light, and therefore, the double-sided displays 100, 200 can be a large-size display and can be widely applied.

The foregoing descriptions are merely exemplary embodiments of the disclosure, but are not intended to limit the disclosure. Any modification, equivalent replacement, or improvement made without departing from the spirit and principle of the disclosure shall fall within the protection scope of the disclosure.

What is claimed is:

1. A double-sided display, comprising:
a driving circuit substrate comprising a first surface, a second surface opposite to the first surface, and a plurality of holes penetrating through the driving circuit substrate from one of the first and second surfaces to the other one of the first and second surfaces;
a front-side light-emitting structure disposed on one of the first and second surfaces;
a back-side light-emitting structure disposed on the other of the first and second surfaces;
a plurality of conductive connections located in the holes;
a plurality of driving electrodes disposed between one of the first and second surfaces and one of the front-side and back-side light-emitting structures; and
a TFT driving circuit disposed between the other one of the first and second surfaces and the other one of the front-side and back-side light-emitting structures, and the TFT driving circuit connected to the driving electrodes via the conducting connections; and
wherein the TFT driving circuit is configured to drive one of the front-side and back-side light-emitting structures to display images, and is further configured to drive the other one of the front-side and back-side light-emitting structures to display images in cooperation with the driving electrodes.

2. The double-sided display according to claim 1, wherein the front-side light-emitting structure and the back-side light-emitting structure share the TFT driving circuit, the TFT driving circuit simultaneously drives the front-side and back-side light-emitting structures.

3. The double-sided display according to claim 1, wherein the double-sided display comprises two TFT driving circuits, one of the two TFT driving circuits drives one of the front-side and back-side light-emitting structures, and the other one of the two TFT driving circuits drives the other one of the front-side and back-side light-emitting structures in cooperation with the driving electrodes that are disposed on the same side of the driving circuit substrate with the other one of the front-side and back-side light-emitting structures.

4. The double-sided display according to claim 3, wherein the two TFT driving circuits comprise a plurality of TFT units, and the TFT units in one of the two TFT driving circuits are connected to the driving electrodes via the conductive connections.

5. The double-sided display according to claim 1, wherein the driving circuit substrate is a non-transparent driving circuit substrate.

6. The double-sided display according to claim 1, wherein the driving electrodes correspond to the holes in a one-one manner, and the holes are respectively filled with the conductive connections.

7. The double-sided display according to claim 1, wherein both of the front-side light-emitting structure and the back-side light-emitting structure are active light-emitting structures or passive light-emitting structures.

8. The double-sided display according to claim 1, wherein one of the front-side light-emitting structure and the back-side light-emitting structure is an active light-emitting structure and the other one is a passive light-emitting structure.

9. A double-sided display, comprising:
a driving circuit substrate comprising a first surface and a second surface opposite to the first surface;
a front-side light-emitting structure disposed on one of the first and second surfaces;
a back-side light-emitting structure disposed on the other one of the first and second surfaces;
a TFT driving circuit disposed on one of the first and second surfaces, and configured to drive the front-side and back-side light-emitting structures to display images.

10. The double-sided display according to claim 9, wherein the TFT driving circuit comprises a plurality of TFT units, the TFT units are disposed on the one of the first and second surfaces, and are configured to drive the front-side and back-side light-emitting structures to display images.

11. The double-sided display according to claim 9, wherein the driving circuit substrate comprises a plurality of holes penetrating through the driving circuit substrate from one of the first and second surfaces to the other one of the first and second surfaces, the TFT driving circuit is connected to one of the front-side and back-side light-emitting structures, and is further connected to the other one of the front-side and back-side light-emitting structures via the holes.

12. The double-sided display according to claim 11, further comprising a plurality of conductive connections, wherein the holes are filled with the conductive connections and the TFT driving circuit is connected to the other one of the front-side and back-side light-emitting structures via the conductive connections.

13. The double-sided display according to claim 11, further comprising a plurality of driving electrodes disposed on the same one of the first and second surfaces with the other one of the front-side and back-side light-emitting structures and connected to the TFT driving circuit, wherein the TFT driving circuit is configured to drive the other one of the front-side and back-side light-emitting structures in cooperation with the driving electrodes.

14. The double-sided display according to claim 9, wherein the front-side and back-side light-emitting structures share the TFT driving circuit, and the TFT driving circuit simultaneously drive the front-side and back-side light-emitting structures.

15. The double-sided display according to claim 9, wherein the double-sided display comprises two TFT driving circuits, one of the two TFT driving circuits is configured to drive one of the front-side and back-side light-emitting structures, and the other one of the two TFT driving circuits is configured to drive the other one of the front-side and back-side light-emitting structures.

16. A method of manufacturing a double-sided display, comprising:
providing a driving circuit substrate comprising a first surface, a second surface opposite to the first surface, and a plurality of holes penetrating through the driving circuit substrate from one of the first and second surfaces to the other one of the first and second surfaces;
providing a TFT driving circuit on one of the first and second surfaces of the driving circuit substrate;
providing driving electrodes on the other one of the first and second surfaces of the driving circuit substrate, and the driving electrodes connected to the TFT driving circuit via the holes;
providing a front-side light-emitting structure on one of the first and second surfaces, and providing a back-side light-emitting structure on the other one of the first and second surfaces;
wherein the TFT driving circuit is disposed between one of the first and second surfaces and one of the front-side and back-side light-emitting structures, and the driving electrodes are disposed between the other one of the first and second surfaces and the other one of the front-side and back-side light-emitting structures.

17. The method according to claim 16, further comprising:
providing a plurality of conductive connections; and
filling the holes with the conductive connections;
wherein the driving electrodes are connected to the TFT driving circuit via the conductive connections.

18. The method according to claim 16, wherein the step of providing a TFT driving circuit on one of the first and second surfaces of the driving circuit substrate comprising:
providing two TFT driving circuits, one of the two TFT driving circuits connected to and configured to drive one of the front-side and back-side light-emitting structures and the other one of the two TFT driving circuits connected to and configured to drive the other one of the front-side and back-side light-emitting structures.

19. The method according to claim 16, wherein the front-side light-emitting structure and the back-side light-emitting structure are active light-emitting structures or passive light-emitting structures.

20. The method according to claim 16, wherein one of the front-side light-emitting structure and the back-side light-emitting structure is an active light-emitting structure and the other one is a passive light-emitting structure.
